(19) United States
(12) Patent Application Publication
(10) Pub. No.: US 2025/0374661 A1
(43) Pub. Date: Dec. 4, 2025

(54) SEMICONDUCTOR DEVICE

(71) Applicant: Samsung Electronics Co., Ltd., Suwon-si (KR)

(72) Inventors: Jinseok LEE, Suwon-si (KR); Woncheol JEONG, Suwon-si (KR); Yoonjeong KIM, Suwon-si (KR); Wangseop LIM, Suwon-si (KR); Youngchai JUNG, Suwon-si (KR); Juseob JEONG, Suwon-si (KR); Kyubong CHOI, Suwon-si (KR); Junsu KONG, Suwon-si (KR); Seojung KIM, Suwon-si (KR); Taehyun RYU, Suwon-si (KR); Yeonho PARK, Suwon-si (KR)

(73) Assignee: Samsung Electronics Co., Ltd., Suwon-si (KR)

(21) Appl. No.: 19/029,161

(22) Filed: Jan. 17, 2025

(30) Foreign Application Priority Data
Jun. 3, 2024 (KR) 10-2024-0072290

(51) Int. Cl. H10D 84/83; H10D 30/00; H10D 30/01; H10D 30/43; H10D 64/01; H10D 64/27; H10D 64/68; H10D 84/01

(52) U.S. Cl. CPC H10D 84/8316; H10D 30/014; H10D 30/019; H10D 30/43; H10D 30/502; H10D 64/017; H10D 64/514; H10D 64/693; H10D 84/0135; H10D 84/0151; H10D 84/832

(57) ABSTRACT

A semiconductor device may include: a field insulating layer; a first gate electrode disposed on the field insulating layer; a plurality of first nanosheets disposed in the first gate electrode; a second gate electrode disposed on the field insulating layer and forming a boundary with the first gate electrode; a plurality of second nanosheets disposed in the second gate electrode; and a gate pattern bridge disposed between the first gate electrode and the second gate electrode and contacting the boundary.

### CROSS-REFERENCE TO RELATED APPLICATION

This application claims the benefit of Korean Patent Application No. 10-2024-0072290, filed on Jun. 3, 2024, in the Korean Intellectual Property Office, the entire disclosure of which is incorporated herein by reference for all purposes.

### BACKGROUND

### 1. Field

The disclosure relates to a semiconductor device.

### 2. Description of the Related Art

A field effect transistor that applies voltage to a gate electrode and generates a gate through which an electron or an electron hole flows by an electric field of a channel is being developed. The above description is information the inventor(s) acquired during the course of conceiving the present disclosure, or already possessed at the time, and is not necessarily art publicly known before the present application was filed.

### SUMMARY

Embodiments provide a semiconductor device with improved gate patterning.

According to one or more example embodiments, a semiconductor device may include: a field insulating layer; a first gate electrode disposed on the field insulating layer; a plurality of first nanosheets disposed in the first gate electrode; a second gate electrode disposed on the field insulating layer and forming a boundary with the first gate electrode; a plurality of second nanosheets disposed in the second gate electrode; and a gate pattern bridge disposed between the first gate electrode and the second gate electrode and contacting the boundary.

A distance between the field insulating layer and the gate pattern bridge may be equal to or greater than a distance between the field insulating layer and a farthest first nanosheet which is farthest from the field insulating layer of the plurality of first nanosheets, or a distance between the field insulating layer and a farthest second nanosheet which is farthest from the field insulating layer of the plurality of second nanosheets.

The gate pattern bridge may overlap the boundary when viewed in a direction that is substantially orthogonal to a direction from the first gate electrode to the second gate electrode.

The gate pattern bridge may include a surface that is at least partially convex toward the field insulating layer.

A surface of the gate pattern bridge facing the field insulating layer may contact a surface of the first gate electrode that is opposite to the field insulating layer and a surface of the second gate electrode that is opposite to the field insulating layer.

The gate pattern bridge may include at least one of silicon nitride, silicon oxycarbonitride, silicon oxynitride, or silicon carbonitride, or a combination thereof.

The semiconductor device further may include: a gate capping pattern in contact with the first gate electrode, the second gate electrode, and the gate pattern bridge.

The semiconductor device further comprising may include: a plurality of first gate spacers disposed on both sides of the first gate electrode; and a plurality of second gate spacers disposed on both sides of the second gate electrode. The gate pattern bridge may be disposed on the plurality of first gate spacers and the plurality of second gate spacers.

The semiconductor device further may include a plurality of gate spacers disposed on both sides of the first gate electrode and the second gate electrode. The gate pattern bridge may be disposed between the plurality of gate spacers.

The first gate electrode and the second gate electrode may be arranged in a line along the field insulating layer.

According to one or more example embodiments, a method of manufacturing a semiconductor device, may include: forming a field insulating layer and a dummy gate on the field insulating layer; forming an etching area by etching the dummy gate; filling the etching area with a filling material; forming a gate pattern bridge by polishing at least a portion of the filling material; and forming a first gate electrode and a second gate electrode in an area corresponding to the dummy gate. The gate pattern bridge may contact a boundary between the first gate electrode and the second gate electrode.

A distance between the field insulating layer and the gate pattern bridge may be equal to or greater than a distance between the field insulating layer and a farthest first nanosheet which is farthest from the field insulating layer of a plurality of first nanosheets, or a distance between the field insulating layer and a farthest second nanosheet which is farthest from the field insulating layer of a plurality of second nanosheets.

The gate pattern bridge may overlap the boundary when viewed in a direction that is substantially orthogonal to a direction from the first gate electrode to the second gate electrode.

The gate pattern bridge may include a surface that is at least partially convex toward the field insulating layer.

A surface of the gate pattern bridge facing the field insulating layer may contact a surface of the first gate electrode that is opposite to the field insulating layer and a surface of the second gate electrode that is opposite to the field insulating layer.

The gate pattern bridge may include at least one of silicon nitride, silicon oxycarbonitride, silicon oxynitride, or silicon carbonitride, or a combination thereof.

The semiconductor device may further include a gate capping pattern in contact with the first gate electrode, the second gate electrode, and the gate pattern bridge.

The semiconductor device further may include: a plurality of first gate spacers disposed on both sides of the first gate electrode; and a plurality of second gate spacers disposed on both sides of the second gate electrode. The gate pattern bridge may be disposed on the plurality of first gate spacers and the plurality of second gate spacers.

The semiconductor device further may include a plurality of gate spacers disposed on both sides of the first gate electrode and the second gate electrode. The gate pattern bridge may be disposed between the plurality of gate spacers.

The first gate electrode and the second gate electrode may be arranged in a line along the field insulating layer.

According to one or more example embodiments, a method of manufacturing a semiconductor device, may include: forming a field insulating layer and a dummy gate on the field insulating layer; performing a photoresist process comprising forming an etching area by etching the dummy gate; forming a gate pattern bridge in the etching area; and forming a first gate electrode and a second gate electrode in an area corresponding to the dummy gate such that the gate pattern bridge contacts a boundary between the first gate electrode and the second gate electrode.

### BRIEF DESCRIPTION OF THE DRAWINGS

The foregoing and other aspects, features, and advantages of embodiments in the disclosure will become apparent from the following detailed description with reference to the accompanying drawings.

FIG. 1 is a perspective view of a semiconductor device according to one or more embodiments;

FIG. 2 is a plane view of a semiconductor device according to one or more embodiments;

FIG. 3 is a cross-sectional view taken along the line 3-3 of the semiconductor

device of FIG. 2;

FIG. 4 is a cross-sectional view taken along the line 4-4 of the semiconductor device of FIG. 2;

FIG. 5 is a cross-sectional view of a semiconductor device in a first direction in a polishing process according to one or more embodiments;

FIG. 6 is a cross-sectional view of a semiconductor device in a second direction in a polishing process according to one or more embodiments;

FIG. 7 is a cross-sectional view of a semiconductor device in a first direction in an etching process according to one or more embodiments;

FIG. 8 is a cross-sectional view of a semiconductor device in a second direction in an etching process according to one or more embodiments;

FIG. 9 is a cross-sectional view of a semiconductor device in a first direction in a deposition process according to one or more embodiments;

FIG. 10 is a cross-sectional view of a semiconductor device in a second direction in a deposition process according to one or more embodiments;

FIG. 11 is a cross-sectional view of a semiconductor device in a first direction in a polishing process according to one or more embodiments;

FIG. 12 is a cross-sectional view of a semiconductor device in a second direction in a polishing process according to one or more embodiments;

FIG. 13 is a cross-sectional view of a semiconductor device in a first direction in a photoresist process according to one or more embodiments;

FIG. 14 is a cross-sectional view of a semiconductor device in a second direction in a photoresist process according to one or more embodiments;

FIG. 15 is a cross-sectional view of a semiconductor device in a second direction in a deposition process according to one or more embodiments;

FIG. 16 is a cross-sectional view of a semiconductor device in a second direction in an etching process according to one or more embodiments;

FIG. 17 is a cross-sectional view of a semiconductor device in a second direction in an etching process according to one or more embodiments;

FIG. 18 is a cross-sectional view of a semiconductor device in a second direction in a deposition process according to one or more embodiments;

FIG. 19 is a plan view of a semiconductor device according to one or more embodiments; and

FIG. 20 is a cross-sectional view taken along the line 20-20 of the semiconductor device of FIG. 19.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the examples with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the examples. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the examples described above and an element having a common function. Unless otherwise mentioned, the descriptions on the examples may be applicable to the following examples and thus, duplicated descriptions will be omitted for conciseness.

As used herein, the terms “substantially”, “approximately”, “generally”, and “about” in reference to a given parameter, property, or condition may include a degree that one of ordinary skill in the art would understand that the given parameter, property, or condition is met with a small degree of variance, such as within acceptable manufacturing tolerances. For example, a parameter that is substantially met may be at least 90% met, at least 95% met, or at least 99% met.

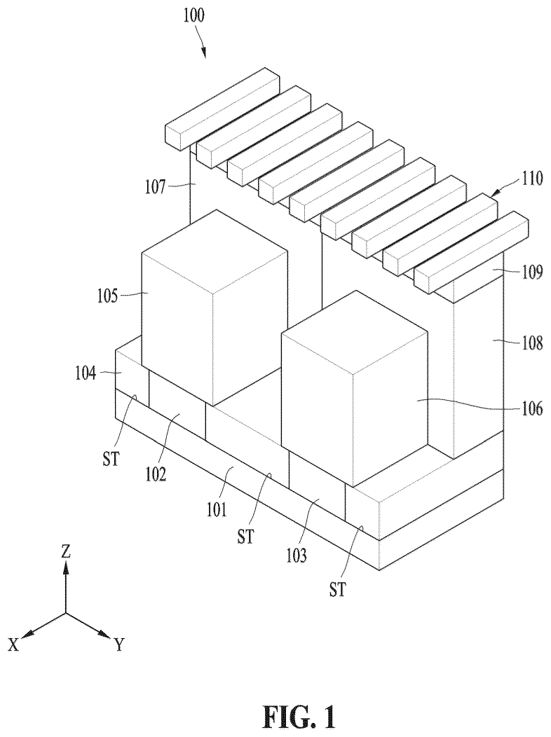

FIG. 1 is a perspective view of a semiconductor device.

Referring to FIG. 1, a semiconductor device 100 may include a logic cell used to control the operation of an electronic device in which the semiconductor device 100 is used by processing data. For example, the logic cell may include a logic circuit such as an inverter or a flip-flop. The semiconductor device 100 may include a plurality of field effect transistors arranged in a line.

The semiconductor device 100 may include a substrate 101. The substrate 101 may include at least one of silicon, germanium, or silicon germanium, or a combination thereof. The substrate 101 may include a plurality of trenches ST that is spaced apart in a certain direction (e.g., a Y direction) of the substrate 101. The substrate 101 may include an insulating material.

The semiconductor device 100 may include a first active pattern 102 and a second active pattern 103. The first active pattern 102 and the second active pattern 103 may each be disposed between the plurality of trenches ST. The first active pattern 102 may be disposed at a first position on the substrate 101. The second active pattern 103 may be disposed at a second position on the substrate 101 that is offset from the first position in one direction (e.g., the Y direction) of the substrate 101. The first active pattern 102 and the second active pattern 103 may have a protruding shape as a portion of the substrate 101.

The semiconductor device 100 may include a field insulating layer 104. The field insulating layer 104 may fill the plurality of trenches ST. The field insulating layer 104 may at least partially surround the first active pattern 102 and the second active pattern 103 on the plurality of trenches ST. The field insulating layer 104 may include a silicon oxide layer.

The semiconductor device 100 may include a plurality of first sources/drains 105. The plurality of first sources/drains 105 may each include an epitaxial pattern formed by a selective epitaxial growth process. The plurality of first sources/drains 105 may each include a semiconductor element (e.g., silicon germanium) having a lattice constant that is greater than a lattice constant of a semiconductor element.

The semiconductor device 100 may include a plurality of second sources/drains 106. The plurality of second sources/drains 106 may each include an epitaxial pattern formed by a selective epitaxial growth process. The plurality of second sources/drains 106 may each include a semiconductor element (e.g., silicon germanium) having a lattice constant that is greater than a lattice constant of a semiconductor element.

The semiconductor device 100 may include a first gate electrode 107 disposed between the first sources/drains 105 that are adjacent to each other. Although FIG. 1 shows that only one first source/drain 105 is disposed on a first side (e.g., a side in an +X direction) of the first gate electrode 107, another first source/drain 105 may be disposed on a second side (e.g., a side in an −X direction) that is opposite to the first side of the first gate electrode 107.

The semiconductor device 100 may include a second gate electrode 108 disposed between the second sources/drains 106 that are adjacent to each other. Although FIG. 1 shows that only one second source/drain 106 is disposed on the first side (e.g., the side in the +X direction) of the second gate electrode 108, another second source/drain 106 may be disposed on the second side (e.g., the side in the −X direction) that is opposite to the first side of the second gate electrode 108.

The semiconductor device 100 may include a gate capping pattern 109 disposed on the first gate electrode 107 and the second gate electrode 108. The gate capping pattern 109 may extend in a direction (e.g., a Y-axis direction) between the first gate electrode 107 and the second gate electrode 108. The gate capping pattern 109 may include at least one of silicon oxynitride, silicon carbonitride, silicon oxycarbonitride, or silicon nitride, or a combination thereof.

The semiconductor device 100 may include a plurality of wiring lines 110 disposed on the gate capping pattern 109. The plurality of wiring lines 110 may be arranged to be spaced apart from each other on the gate capping pattern 109. The plurality of wiring lines 110 may each include at least one of a power line and a signal line.

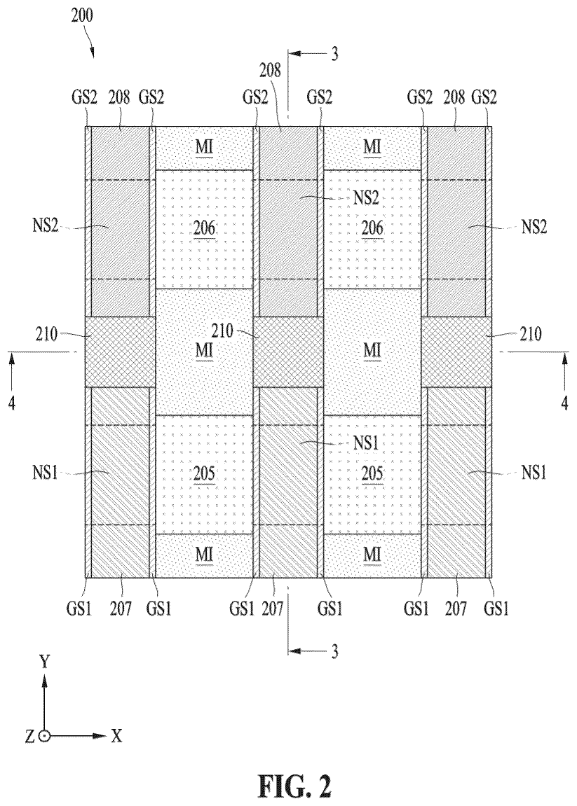

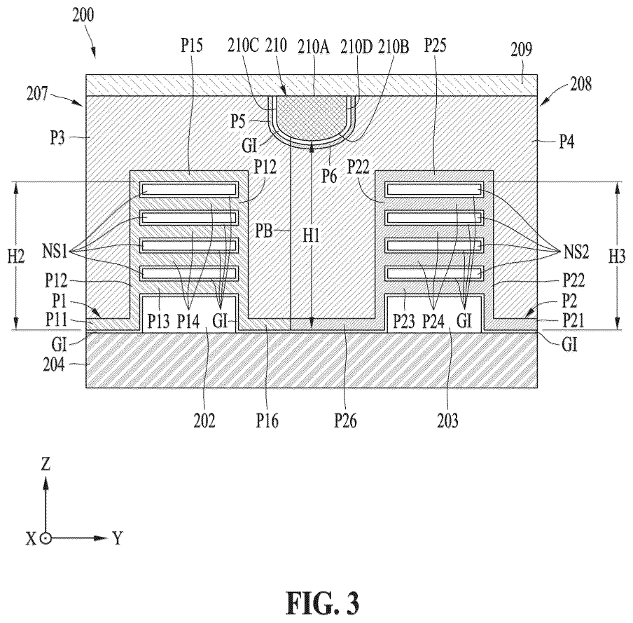

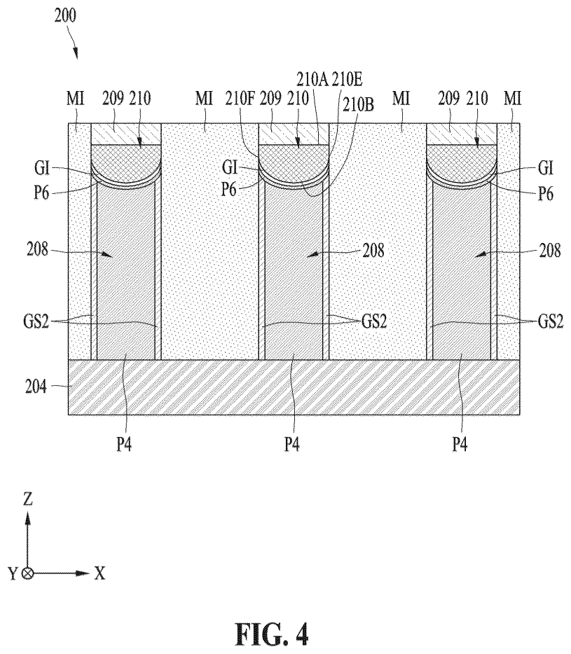

FIG. 2 is a plane view of a semiconductor device. FIG. 3 is a cross-sectional view taken along the line 3-3 of the semiconductor device of FIG. 2. FIG. 4 is a cross-sectional view taken along the line 4-4 of the semiconductor device of FIG. 2.

Referring to FIGS. 2 to 4, a semiconductor device 200 may include a field insulating layer 204. For example, the field insulating layer 204 may include a silicon oxide layer.

The semiconductor device 200 may include a first active pattern 202 and a second active pattern 203. The first active pattern 202 and the second active pattern 203 may be spaced apart from each other on the field insulating layer 204 in a certain direction (e.g., a Y-axis direction) of the field insulating layer 204.

The semiconductor device 200 may include a plurality of first sources/drains 205 and a plurality of second sources/drains 206. The plurality of first sources/drains 205 may be arranged to be spaced apart from each other in a first direction (e.g., an X direction) of the field insulating layer 204. The plurality of second sources/drains 206 may be arranged to be spaced apart from each other in the first direction (e.g., the X direction) of the field insulating layer 204. The plurality of first sources/drains 205 and the plurality of second sources/drains 206 may be spaced apart from each other in a second direction (e.g., a Y direction) that is different (e.g., orthogonal to the first direction) from the first direction of the field insulating layer 204.

The semiconductor device 200 may include a plurality of first gate electrodes 207. The plurality of first gate electrodes 207 may be arranged to be spaced apart from each other in the first direction (e.g., the X direction) of the field insulating layer 204. The first gate electrodes 207 that are adjacent to each other may be connected to both sides (e.g., a side in an +X direction and a side in an −X direction) of the plurality of first sources/drains 205.

The semiconductor device 200 may include a plurality of first nanosheets NS1 in a first stack. The plurality of first nanosheets NS1 may be arranged above the first active pattern 202 and be spaced apart from each other in the height direction (e.g., a Z direction) of the plurality of first gate electrodes 207.

The semiconductor device 200 may include a plurality of first gate spacers GS1. The plurality of first gate spacers GS1 may each be disposed on both sides (e.g., a side in an +X direction and a side in an −X direction of FIG. 4) of the plurality of first gate electrodes 207. The plurality of first gate spacers GS1 may each include at least one of silicon carbonitride, silicon oxycarbonitride, or silicon nitride, or a combination thereof.

The semiconductor device 200 may include a plurality of second gate electrodes 208. The plurality of second gate electrodes 208 may be arranged to be spaced apart from each other in the first direction (e.g., the X direction) of the field insulating layer 204. The second gate electrodes 208 that are adjacent to each other may be connected to both sides (e.g., the side in the +X direction and the side in the −X direction) of the plurality of second sources/drains 206. The plurality of second gate electrodes 208 may be electrically connected to the plurality of first gate electrodes 207, respectively.

The semiconductor device 200 may include a plurality of second nanosheets NS2 in a second stack. The plurality of second nanosheets NS2 may be arranged above the second active pattern 203 and be spaced apart from each other in the height direction (e.g., the Z direction) of the plurality of second gate electrodes 208.

The semiconductor device 200 may include a plurality of second gate spacers GS2. The plurality of second gate spacers GS2 may each be disposed on both sides (e.g., the side in the +X direction and the side in the −X direction of FIG. 4) of the plurality of second gate electrodes 208. The plurality of second gate spacers GS2 may each include at least one of silicon carbonitride, silicon oxycarbonitride, or silicon nitride, or a combination thereof.

The semiconductor device 200 may include a plurality of gate capping patterns 209. The plurality of gate capping patterns 209 is omitted from FIG. 2 for ease of description. The plurality of gate capping patterns 209 may each be disposed on the plurality of first gate electrodes 207 and the plurality of second gate electrodes 208. The plurality of gate capping patterns 209 may each extend in the longitudinal direction (e.g., the Y direction) of the plurality of first gate electrodes 207 and the plurality of second gate electrodes 208.

The plurality of first gate electrodes 207 may include a first electrode pattern P1. The first electrode pattern P1 may include one of a p-type work function metal or an n-type work function metal. The first electrode pattern P1 may include a metal nitride layer. For example, the first electrode pattern PI may include at least one of titanium, tantalum, aluminum, tungsten, or molybdenum, or a combination thereof. The first electrode pattern P1 may further include nitrogen. The first electrode pattern P1 may further include carbon.

The first electrode pattern P1 may include a first pattern portion P11 disposed on a first side (e.g., a side in a −Y direction) of the first active pattern 202. The first pattern portion P11 may extend along the field insulating layer 204 in the second direction (e.g., the Y direction) of the field insulating layer 204.

The first electrode pattern PI may include a plurality of second pattern portions P12. The plurality of second pattern portions P12 may extend along at least a portion of both sides (e.g., the side in the −Y direction and a side in a +Y direction) of the first active pattern 202 and along the stack direction (e.g., the Z direction) of the plurality of first nanosheets NS1. The second pattern portion P12 of the plurality of second pattern portions P12 disposed on the first side (e.g., the side in the −Y direction) of the first active pattern 202 may be connected to the first pattern portion P11.

The first electrode pattern P1 may include a third pattern portion P13 disposed between the first nanosheet NS1 of the plurality of first nanosheets NS1 that is closest to the first active pattern 202 and the first active pattern 202. The third pattern portion P13 may extend along the first active pattern 202 in the sheet direction (e.g., the Y direction) of the plurality of first nanosheets NS1. The third pattern portion P13 may be connected to the plurality of second pattern portions P12.

The first electrode pattern P1 may include one or more fourth pattern portions P14 each disposed between the first nanosheets NS1 that are adjacent to each other. The one or more fourth pattern portions P14 may extend in the sheet direction (e.g., the Y direction) of the plurality of first nanosheets NS1. The one or more fourth pattern portions P14 may be connected to the plurality of second pattern portions P12.

The first electrode pattern P1 may include a fifth pattern portion P15 disposed on the first nanosheet NS1 of the plurality of first nanosheets NS1 that is farthest from the first active pattern 202. The fifth pattern portion P15 may extend in the sheet direction (e.g., the Y direction) of the plurality of first nanosheets NS1. The fifth pattern portion P15 may be connected to the plurality of second pattern portions P12.

The first electrode pattern P1 may include a sixth pattern portion P16 disposed on a second side (e.g., the side in the +Y direction) that is opposite to the first side of the first active pattern 202. The sixth pattern portion P16 may extend along the field insulating layer 204 in the second direction (e.g., the Y direction) of the field insulating layer 204. The sixth pattern portion P16 may be connected to the second pattern portion P12 of the plurality of second pattern portions P12 disposed on the second side (e.g., the side in the +Y direction) that is opposite to the first side of the first active pattern 202.

The plurality of second gate electrodes 208 may include a second electrode pattern P2. The second electrode pattern P2 may include a different material from the first electrode pattern P1. For example, the first electrode pattern P1 may include one of a p-type work function metal or an n-type work function metal, and the second electrode pattern P2 may include a different type of work function metal. The second electrode pattern P2 may include a metal nitride layer. For example, the second electrode pattern P2 may include at least one of titanium, tantalum, aluminum, tungsten, or molybdenum, or a combination thereof. The second electrode pattern P2 may further include nitrogen. The second electrode pattern P2 may further include carbon.

The second electrode pattern P2 may include a first pattern portion P21 disposed on the second side (e.g., the side in the +Y direction) of the second active pattern 203. The first pattern portion P21 may extend along the field insulating layer 204 in the second direction (e.g., the Y direction) of the field insulating layer 204.

The second electrode pattern P2 may include a plurality of second pattern portions P22. The plurality of second pattern portions P22 may extend along at least a portion of both sides (e.g., the side in the −Y direction and the side in the +Y direction) of the second active pattern 203 and along the stack direction (e.g., the Z direction) of the plurality of second nanosheets NS2. The second pattern portion P22 of the plurality of second pattern portions P22 disposed on the second side (e.g., the side in the +Y direction) of the second active pattern 203 may be connected to the first pattern portion P21.

The second electrode pattern P2 may include a third pattern portion P23 disposed between the second nanosheet NS2 that is closest to the second active pattern 203 and the second active pattern 203. The third pattern portion P23 may extend along the second active pattern 203 in the sheet direction (e.g., the Y direction) of the plurality of second nanosheets NS2. The third pattern portion P23 may be connected to the plurality of second pattern portions P22.

The second electrode pattern P2 may include one or more fourth pattern portions P24 each disposed between the second nanosheets NS2 that are adjacent to each other. The one or more fourth pattern portions P24 may extend in the sheet direction (e.g., the Y direction) of the plurality of second nanosheets NS2. The one or more fourth pattern portions P24 may be connected to the plurality of second pattern portions P22.

The second electrode pattern P2 may include a fifth pattern portion P25 disposed on the second nanosheet NS2 that is farthest from the second active pattern 203. The fifth pattern portion P25 may extend in the sheet direction (e.g., the Y direction) of the plurality of second nanosheets NS2. The fifth pattern portion P25 may be connected to the plurality of second pattern portions P22.

The second electrode pattern P2 may include a sixth pattern portion P26 disposed on the first side (e.g., the side in the −Y direction) that is opposite to the second side of the second active pattern 203. The sixth pattern portion P26 may extend along the field insulating layer 204 in the second direction (e.g., the Y direction) of the field insulating layer 204. The sixth pattern portion P26 may be connected to the second pattern portion P22 of the plurality of second pattern portions P22 disposed on the first side (e.g., the side in the −Y direction) that is opposite to the second side of the second active pattern 203. The sixth pattern portion P16 of the plurality of first gate electrodes 207 and the sixth pattern portion P26 of the plurality of second gate electrodes 208 may contact each other and form a boundary PB.

The plurality of first gate electrodes 207 may include a third electrode pattern P3. The third electrode pattern P3 may be disposed on the first electrode pattern P1. The third electrode pattern P3 may include a metal having resistance that is less than the resistance of the first electrode pattern P1. For example, the third electrode pattern P3 may include at least one of tungsten, aluminum, titanium, or tantalum, or a combination thereof.

The plurality of second gate electrodes 208 may include a fourth electrode pattern P4. The fourth electrode pattern P4 may be disposed on the second electrode pattern P2. The fourth electrode pattern P4 may include a metal having resistance that is less than the resistance of the second electrode pattern P2. For example, the fourth electrode pattern P4 may include at least one of tungsten, aluminum, titanium, or tantalum, or a combination thereof.

The semiconductor device 200 may include a plurality of gate pattern bridges 210. The plurality of gate pattern bridges 210 may consistently form the boundary PB between the plurality of first gate electrodes 207 and the plurality of second gate electrodes 208 in a predetermined range regardless of process dispersion in a certain process (e.g., a metal patterning process after a photoresist process) of a method of manufacturing the semiconductor device 200.

The plurality of gate pattern bridges 210 may be disposed between the plurality of first gate electrodes 207 and the plurality of second gate electrodes 208. The plurality of gate pattern bridges 210 may overlap the boundary PB when viewed in a third direction (e.g., the Z direction) of the field insulating layer 204. This may prevent at least a portion of the plurality of first gate electrodes 207 and at least a portion of the plurality of second gate electrodes 208 from being substantially lost during manufacture of the semiconductor device 200, and the boundary PB formed by the plurality of first gate electrodes 207 and the plurality of second gate electrodes 208 may be consistently positioned under the plurality of gate pattern bridges 210.

The plurality of gate pattern bridges 210 may include a first surface 210A that is opposite to the field insulating layer 204, a second surface 210B facing the field insulating layer 204 and opposite to the first surface 210A, a first side surface 210C facing the plurality of first gate electrodes 207 and connected to the first surface 210A and the second surface 210B, a second side surface 210D facing the plurality of second gate electrodes 208, connected to the first surface 210A and the second surface 210B, and opposite to the first side surface 210C, a third side surface 210E facing a different one of the plurality of gate pattern bridges 210 in the first direction (e.g., the X direction) of the field insulating layer 204 and connected to the first surface 210A, the second surface 210B, the first side surface 210C, and the second side surface 210D, and a fourth side surface 210F facing opposite to one of the plurality of gate pattern bridges 210 in the first direction (e.g., the X direction) of the field insulating layer 204, connected to the first surface 210A, the second surface 210B, the first side surface 210C, and the second side surface 210D, and opposite to the third side surface 210E.

The first surface 210A of the plurality of gate pattern bridges 210 may be coplanar with a surface (e.g., a surface in a +Z direction) of the plurality of first gate electrodes 207 that is opposite to the field insulating layer 204 and a surface (e.g., the surface in the +Z direction) of the plurality of second gate electrodes 208 that is opposite to the field insulating layer 204. The first surface 210A of the plurality of gate pattern bridges 210 may contact the plurality of gate capping patterns 209 respectively corresponding to the plurality of gate pattern bridges 210.

The plurality of gate pattern bridges 210 may have an at least partially convex shape. For example, the second surface 210B of the plurality of gate pattern bridges 210 may be at least partially curved in a direction (e.g., a −Z direction) toward the field insulating layer 204. The second surface 210B of the plurality of gate pattern bridges 210 may be substantially flat overall.

A distance H1 between the second surface 210B of the plurality of gate pattern bridges 210 and a surface (e.g., the surface in the +Z direction) of the field insulating layer 204 viewed by the plurality of gate pattern bridges 210 may be the same as or greater than a distance H2 between a surface (e.g., the surface in the +Z direction) that is opposite to the field insulating layer 204 of surfaces of the first nanosheet NS1 of the plurality of first nanosheets NS1 that is farthest from the field insulating layer 204 and a surface (e.g., the surface in the +Z direction) of the field insulating layer 204 viewed by the plurality of gate pattern bridges 210 or a distance H3 between a surface (e.g., the surface in the +Z direction) that is opposite to the field insulating layer 204 of surfaces of the second nanosheet NS2 of the plurality of second nanosheets NS2 that is farthest from the field insulating layer 204 and a surface (e.g., the surface in the +Z direction) of the field insulating layer 204 viewed by the plurality of gate pattern bridges 210.

The plurality of gate pattern bridges 210 may include at least one of silicon nitride, silicon oxycarbonitride, silicon oxynitride, or silicon carbonitride, or a combination thereof.

The plurality of first gate electrodes 207 may include a fifth electrode pattern P5. The fifth electrode pattern P5 may be disposed on the first side surface 210C of the plurality of gate pattern bridges 210. The fifth electrode pattern P5 may also be disposed on at least one area of the second surface 210B of the plurality of gate pattern bridges 210. The fifth electrode pattern P5 may include the same material as the first electrode pattern P1. The fifth electrode pattern P5 may include a metal nitride layer. For example, the fifth electrode pattern P5 may include at least one of titanium, tantalum, aluminum, tungsten, or molybdenum, or a combination thereof. The fifth electrode pattern P5 may further include nitrogen. The fifth electrode pattern P5 may further include carbon.

The plurality of second gate electrodes 208 may include a sixth electrode pattern P6. The sixth electrode pattern P6 may be disposed on at least one area of the second surface 210B of the plurality of gate pattern bridges 210 and the second side surface 210D. The sixth electrode pattern P6 may not be disposed on the second side surface 210D of the plurality of gate pattern bridges 210. The sixth electrode pattern P6 may include the same material as the second electrode pattern P2. The sixth electrode pattern P6 may include a metal nitride layer. For example, the sixth electrode pattern P6 may include at least one of titanium, tantalum, aluminum, tungsten, or molybdenum, or a combination thereof. The sixth electrode pattern P6 may further include nitrogen. The sixth electrode pattern P6 may further include carbon.

The semiconductor device 200 may include a plurality of gate insulating layers GI. The plurality of gate insulating layers GI may be disposed between the field insulating layer 204 and the first electrode pattern P1, between the first active pattern 202 and the first electrode pattern P1, between the first electrode pattern P1 and the plurality of first nanosheets NS1, between the field insulating layer 204 and the second electrode pattern P2, between the second active pattern 203 and the second electrode pattern P2, and between the second electrode pattern P2 and the plurality of second nanosheets NS2. The plurality of gate insulating layers GI may be disposed between the plurality of first gate electrodes 207 and the plurality of first gate spacers GS1 and between the plurality of second gate electrodes 208 and the plurality of second gate spacers GS2. The plurality of gate insulating layers GI may be disposed between the plurality of first gate electrodes 207 and the plurality of gate pattern bridges 210 and between the plurality of second gate electrodes 208 and the plurality of gate pattern bridges 210. The plurality of gate insulating layers GI may include at least one of a silicon oxide layer, a silicon oxynitride layer, or a high-k layer, or a combination thereof. The high-k layer may include a material having higher permittivity than the permittivity of the silicon oxide layer. For example, the high-k layer may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate, or a combination thereof.

A plurality of interlayer insulating layers MI may be disposed between the first gate electrodes 207 that are adjacent to each other in the first direction (e.g., the X direction) of the field insulating layer 204 on the field insulating layer 204, between the plurality of first sources/drains 205 and the plurality of second sources/drains 206 arranged in the second direction (e.g., the Y direction) of the field insulating layer 204, and between the second gate electrodes 208 that are adjacent to each other in the first direction (e.g., the X direction) of the field insulating layer 204. The plurality of interlayer insulating layers MI may at least partially cover a portion (e.g., a portion in the +/−Y direction) of the plurality of first sources/drains 205, a portion (e.g., a portion in the +/−Y direction) of the plurality of second sources/drains 206, the plurality of first gate spacers GS1, and the plurality of second gate spacers GS2. The plurality of interlayer insulating layers MI may include a silicon oxide layer.

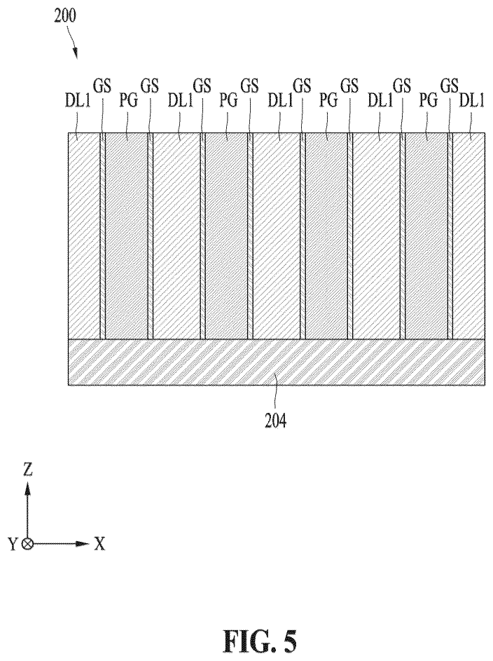

FIGS. 5 to 18 are diagrams illustrating a method of manufacturing a semiconductor device. The method is described below with reference to FIGS. 5 to 18 sequentially but is not limited thereto and may include a process not shown in the drawings or may not include at least one of the processes, and the order of the processes may vary.

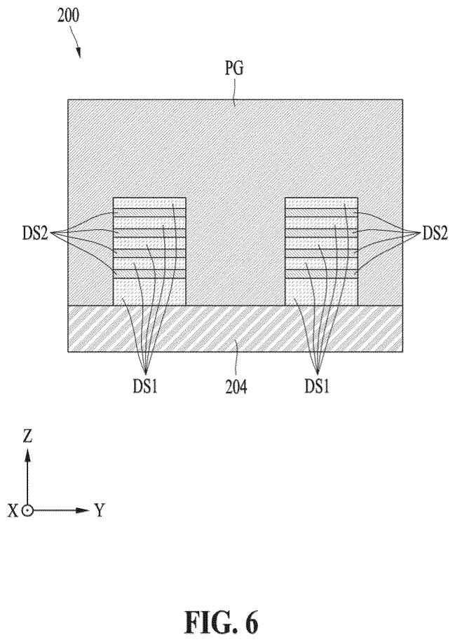

FIG. 5 is a cross-sectional view of a semiconductor device in a first direction in a polishing process, and FIG. 6 is a cross-sectional view of a semiconductor device in a second direction in a polishing process.

Referring to FIGS. 5 and 6, a method of manufacturing the semiconductor device 200 may include forming a plurality of dummy gates PG arranged in a first direction (e.g., an X direction) on the field insulating layer 204, a plurality of gate spacers GS on both sides of the plurality of dummy gates PG, and insulating layers DLI on both sides of the plurality of dummy gates PG and in contact with the plurality of gate spacers GS. Each of the plurality of dummy gates PG may include a polysilicon material. The plurality of dummy gates PG may include a plurality of active sheets DS1 made of silicon and a plurality of dummy sheets DS2 made of silicon germanium, which are alternately disposed on the field insulating layer 204. The method of manufacturing the semiconductor device 200 may include polishing a portion (e.g., a portion in a +Z direction) that is opposite to the field insulating layer 204 so that the plurality of dummy gates PG is separated from each other.

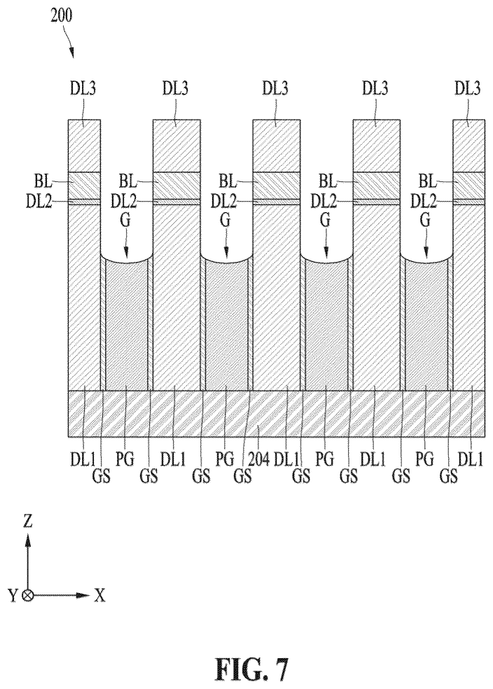

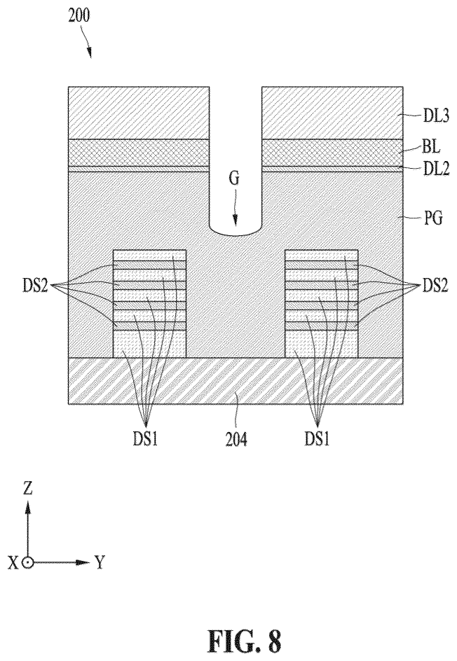

FIG. 7 is a cross-sectional view of a semiconductor device in a first direction in an etching process, and FIG. 8 is a cross-sectional view of a semiconductor device in a second direction in an etching process.

Referring to FIGS. 7 and 8, a method of manufacturing the semiconductor device 200 may include depositing insulating layers DL2 on the plurality of dummy gates PG, the plurality of gate spacers GS, and the insulating layers DL1, depositing bridge layers BL (for example, made of silicon nitride) on the insulating layers DL2, and depositing insulating layers DL3 on the bridge layers BL. The method of manufacturing the semiconductor device 200 may include forming grooves G between the insulating layers DLI by etching a portion of the plurality of dummy gates PG and at least a portion of the plurality of gate spacers GS in addition to the insulating layers DL2, the bridge layers BL, and the insulating layers DL3, which are deposited.

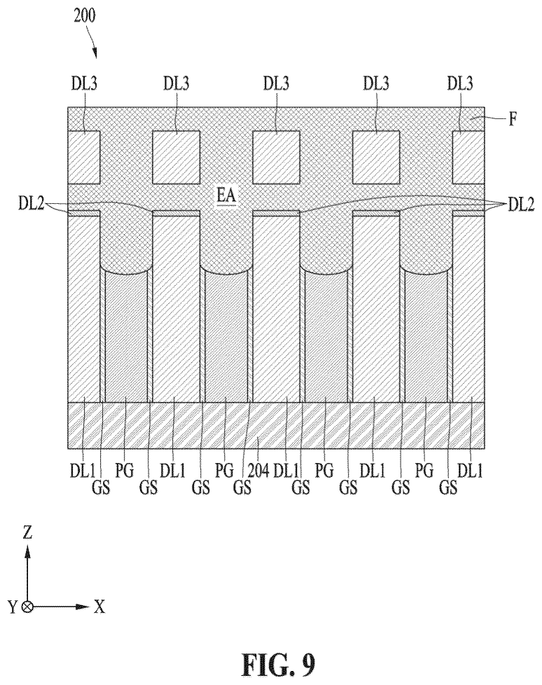

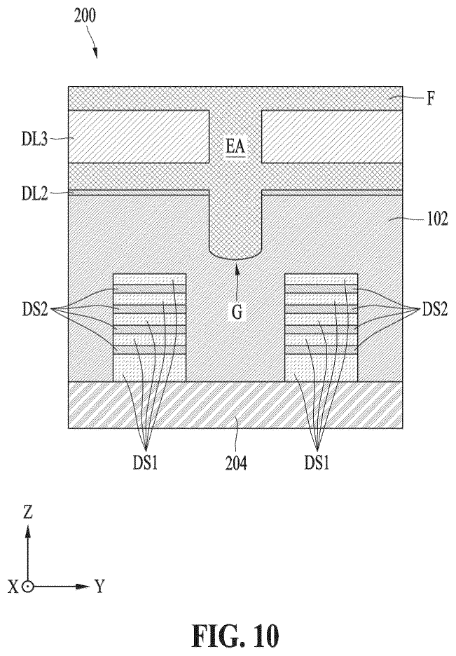

FIG. 9 is a cross-sectional view of a semiconductor device in a first direction in a deposition process, and FIG. 10 is a cross-sectional view of a semiconductor device in a second direction in a deposition process.

Referring to FIGS. 9 and 10, a method of manufacturing the semiconductor device 200 may include depositing an etching area EA including the grooves G described above with reference to FIGS. 7 and 8 with a filling material F with a material (e.g., silicon nitride) of the bridge layers BL.

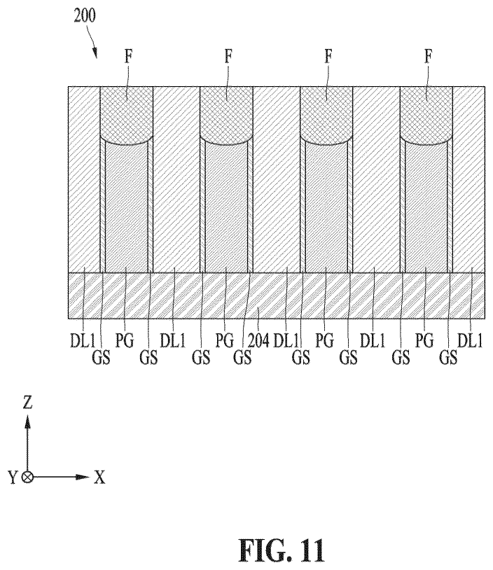

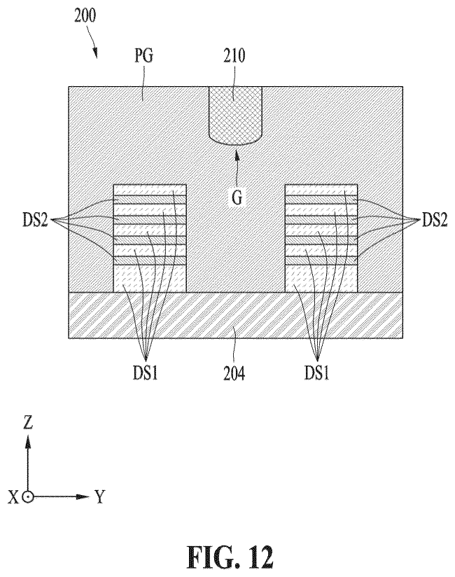

FIG. 11 is a cross-sectional view of a semiconductor device in a first direction in a polishing process, and FIG. 12 is a cross-sectional view of a semiconductor device in a second direction in a polishing process.

Referring to FIGS. 11 and 12, a method of manufacturing the semiconductor device 200 may include forming the plurality of gate pattern bridges 210 having a shape that is complementary to a shape of the grooves G by polishing the insulating layers DL2 and DL3 in addition to a portion of the deposited filling material F described above with reference to FIGS. 9 and 10.

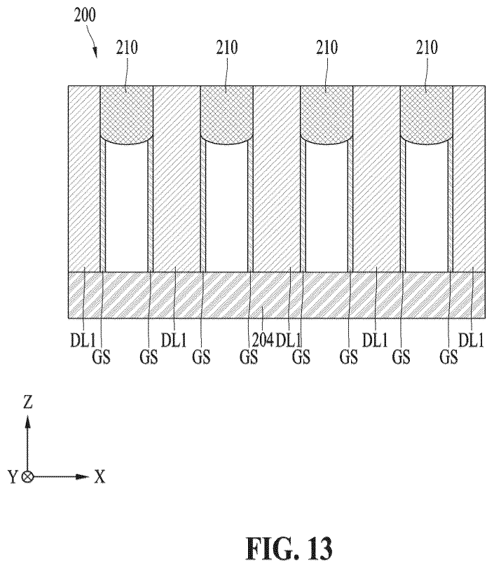

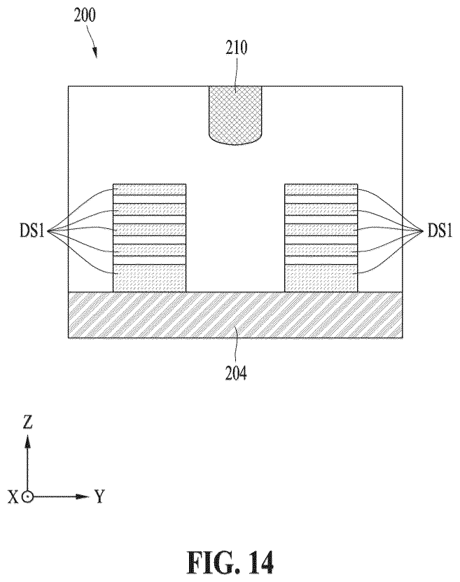

FIG. 13 is a cross-sectional view of a semiconductor device in a first direction in a photoresist process, and FIG. 14 is a cross-sectional view of a semiconductor device in a second direction in a photoresist process.

Referring to FIGS. 13 and 14, a method of manufacturing the semiconductor device 200 may include removing a plurality of dummy gates (e.g., the plurality of dummy gates PG of FIGS. 11 and 12) and a plurality of dummy sheets (e.g., the plurality of dummy sheets DS2 of FIGS. 11 and 12), leaving the plurality of gate spacers GS between the insulating layers DL1.

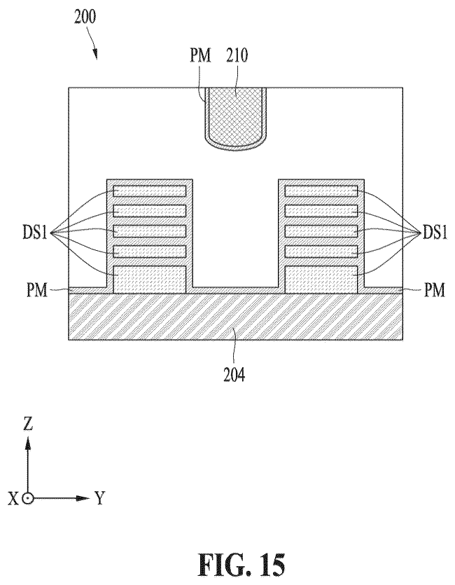

FIG. 15 is a cross-sectional view of a semiconductor device in a second direction in a deposition process.

Referring to FIG. 15, a method of manufacturing the semiconductor device 200 may include depositing a first metal material PM (e.g., a p-type work function metal). The deposited first metal material PM may surround the plurality of active sheets DS1 along the field insulating layer 204. The deposited first metal material PM may surround the plurality of gate pattern bridges 210.

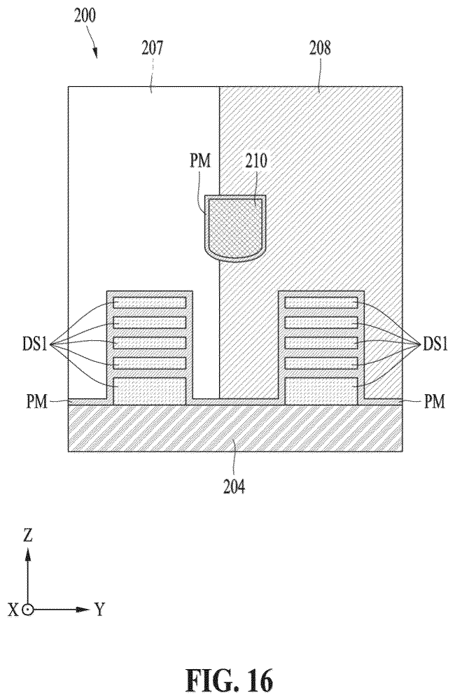

FIG. 16 is a cross-sectional view of a semiconductor device in a second direction in an etching process.

Referring to FIG. 16, a method of manufacturing the semiconductor device 200 may include patterning, with a metal, an area corresponding to the plurality of first gate electrodes 207 and an area corresponding to the plurality of second gate electrodes 208. The method of manufacturing the semiconductor device 200 may include etching the area corresponding to the plurality of first gate electrodes 207. While the area corresponding to the plurality of first gate electrodes 207 is etched, the boundary PB in which the area corresponding to the plurality of first gate electrodes 207 contacts the area corresponding to the plurality of second gate electrodes 208 may be defined under the plurality of gate pattern bridges 210.

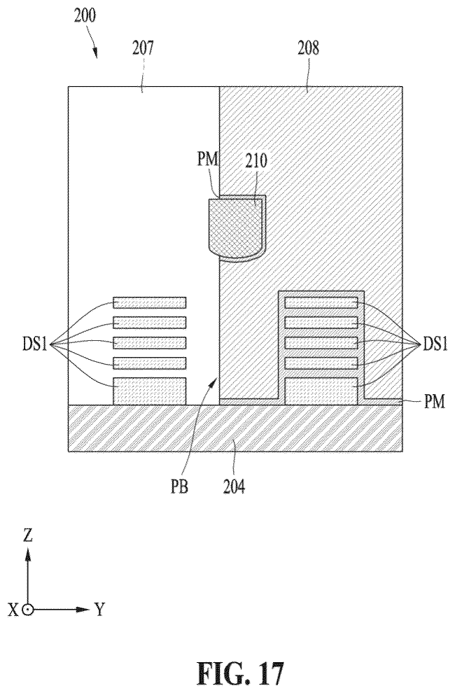

FIG. 17 is a cross-sectional view of a semiconductor device in a second direction in an etching process.

Referring to FIG. 17, a method of manufacturing the semiconductor device 200 may include removing the first metal material PM in the area corresponding to the plurality of first gate electrodes 207. For example, the first metal material PM may be removed by wet etching. In this case, the first metal material PM in the area corresponding to the plurality of second gate electrodes 208 may not be removed.

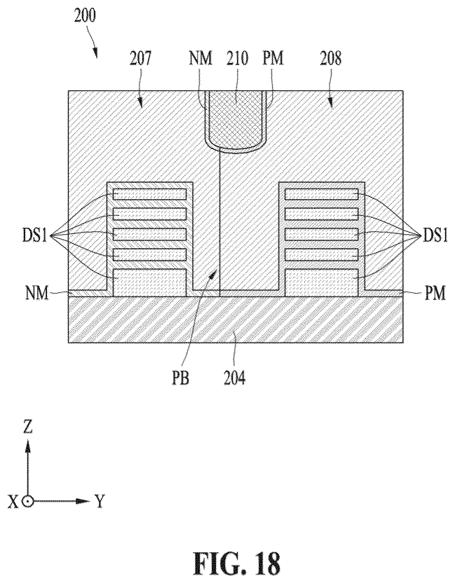

FIG. 18 is a cross-sectional view of a semiconductor device in a second direction in a deposition process.

Referring to FIG. 18, a method of manufacturing the semiconductor device 200 may include depositing a second metal material NM (e.g., an n-type work function metal). The deposited second metal material NM may surround the plurality of active sheets DS1 along the field insulating layer 204. The deposited second metal material NM may form the boundary PB with the first metal material PM. The boundary PB may be positioned below the plurality of gate pattern bridges 210. The method of manufacturing the semiconductor device 200 may include patterning the area corresponding to the plurality of first gate electrodes 207 with a metal.

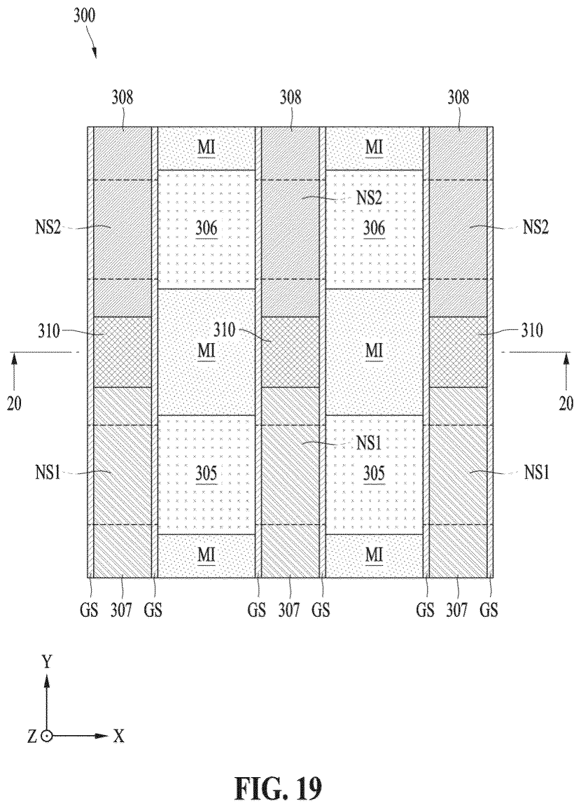

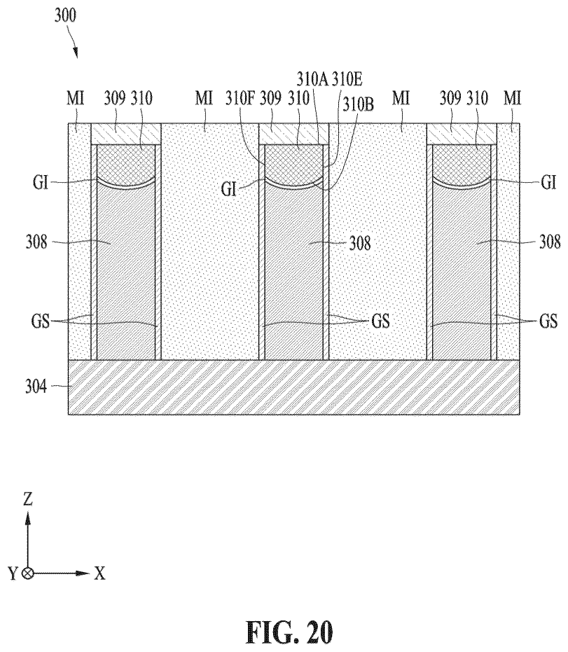

FIG. 19 is a plan view of a semiconductor device, and FIG. 20 is a cross-sectional view taken along the line 20-20 of the semiconductor device of FIG. 19.

Referring to FIGS. 19 and 20, a semiconductor device 300 may include a field insulating layer 304, a plurality of first sources/drains 305, a plurality of second sources/drains 306, a plurality of first gate electrodes 307, a plurality of second gate electrodes 308, a plurality of gate capping patterns 309, a plurality of interlayer insulating layers MI, and a plurality of gate pattern bridges 310. The plurality of first gate electrodes 307 may each include a first gate electrode 307A and a plurality of first nanosheets 307B. The plurality of second gate electrodes 308 may each include a second gate electrode 308A and a plurality of second nanosheets 308B.

The semiconductor device 300 may include a plurality of gate spacers GS. Each of the plurality of gate pattern bridges 310 may be disposed between the plurality of gate spacers GS. For example, a third side surface 310E of the plurality of gate pattern bridges 310 may contact the plurality of gate spacers GS on a first side (e.g., a side in an +X direction) of the plurality of gate pattern bridges 310, and a fourth side surface 310F of the plurality of gate pattern bridges 310 may contact the plurality of gate spacers GS on a second side (e.g., a side in an −X direction) that is opposite to the first side of the plurality of gate pattern bridges 310. The plurality of gate spacers GS may extend along the second gate electrode 308A across the plurality of gate pattern bridges 310 along the first gate electrode 307A. The plurality of gate spacers GS may not be separated into a first gate spacer corresponding to the plurality of first gate electrodes 307 and a second gate spacer corresponding to the plurality of second gate electrodes 308 by the plurality of gate pattern bridges 310.

Interlayer insulating layers GI may be disposed between the second surface 210B of the plurality of gate pattern bridges 210 and the plurality of first gate electrodes 207 and between the second surface 210B of the plurality of gate pattern bridges 210 and the plurality of second gate electrodes 208. The interlayer insulating layers GI may not be disposed between the second surface 210B of the plurality of gate pattern bridges 210 and the plurality of first gate spacers GS1 and between the second surface 210B of the plurality of gate pattern bridges 210 and the plurality of second gate spacers GS2.

Although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and/or equivalents of the claims are within the scope of the following claims.

1. A semiconductor device comprising:
a field insulating layer;
a first gate electrode disposed on the field insulating layer;
a plurality of first nanosheets disposed in the first gate electrode;
a second gate electrode disposed on the field insulating layer and forming a boundary with the first gate electrode;
a plurality of second nanosheets disposed in the second gate electrode; and
a gate pattern bridge disposed between the first gate electrode and the second gate electrode and contacting the boundary.

2. The semiconductor device of claim 1, wherein a distance between the field insulating layer and the gate pattern bridge is equal to or greater than a distance between the field insulating layer and a farthest first nanosheet which is farthest from the field insulating layer of the plurality of first nanosheets, or a distance between the field insulating layer and a farthest second nanosheet which is farthest from the field insulating layer of the plurality of second nanosheets.

3. The semiconductor device of claim 1, wherein the gate pattern bridge overlaps the boundary when viewed in a direction that is substantially orthogonal to a direction from the first gate electrode to the second gate electrode.

4. The semiconductor device of claim 1, wherein the gate pattern bridge comprises a surface that is at least partially convex toward the field insulating layer.

5. The semiconductor device of claim 1, wherein a surface of the gate pattern bridge facing the field insulating layer contacts a surface of the first gate electrode that is opposite to the field insulating layer and a surface of the second gate electrode that is opposite to the field insulating layer.

6. The semiconductor device of claim 1, wherein the gate pattern bridge comprises at least one of silicon nitride, silicon oxycarbonitride, silicon oxynitride, or silicon carbonitride, or a combination thereof.

7. The semiconductor device of claim 1, further comprising:
a gate capping pattern in contact with the first gate electrode, the second gate electrode, and the gate pattern bridge.

8. The semiconductor device of claim 1, further comprising:
a plurality of first gate spacers disposed on both sides of the first gate electrode; and
a plurality of second gate spacers disposed on both sides of the second gate electrode,
wherein the gate pattern bridge is disposed on the plurality of first gate spacers and the plurality of second gate spacers.

9. The semiconductor device of claim 1, further comprising:
a plurality of gate spacers disposed on both sides of the first gate electrode and the second gate electrode,
wherein the gate pattern bridge is disposed between the plurality of gate spacers.

10. The semiconductor device of claim 1, wherein the first gate electrode and the second gate electrode are arranged in a line along the field insulating layer.

11. A method of manufacturing a semiconductor device, the method comprising:
forming a field insulating layer and a dummy gate on the field insulating layer;
forming an etching area by etching the dummy gate;
filling the etching area with a filling material;
forming a gate pattern bridge by polishing at least a portion of the filling material; and
forming a first gate electrode and a second gate electrode in an area corresponding to the dummy gate,
wherein the gate pattern bridge contacts a boundary between the first gate electrode and the second gate electrode.

12. The method of claim 11, wherein a distance between the field insulating layer and the gate pattern bridge is equal to or greater than a distance between the field insulating layer and a farthest first nanosheet which is farthest from the field insulating layer of a plurality of first nanosheets, or a distance between the field insulating layer and a farthest second nanosheet which is farthest from the field insulating layer of a plurality of second nanosheets.

13. The method of claim 11, wherein the gate pattern bridge overlaps the boundary when viewed in a direction that is substantially orthogonal to a direction from the first gate electrode to the second gate electrode.

14. The method of claim 11, wherein the gate pattern bridge comprises a surface that is at least partially convex toward the field insulating layer.

15. The method of claim 11, wherein a surface of the gate pattern bridge facing the field insulating layer contacts a surface of the first gate electrode that is opposite to the field insulating layer and a surface of the second gate electrode that is opposite to the field insulating layer.

16. The method of claim 11, wherein the gate pattern bridge comprises at least one of silicon nitride, silicon oxycarbonitride, silicon oxynitride, or silicon carbonitride, or a combination thereof.

17. (canceled)

18. The method of claim 11, wherein the semiconductor device further comprises:
a plurality of first gate spacers disposed on both sides of the first gate electrode; and
a plurality of second gate spacers disposed on both sides of the second gate electrode,
wherein the gate pattern bridge is disposed on the plurality of first gate spacers and the plurality of second gate spacers.

19. The method of claim 11,
wherein the semiconductor device further comprises a plurality of gate spacers disposed on both sides of the first gate electrode and the second gate electrode,
wherein the gate pattern bridge is disposed between the plurality of gate spacers.

20. The method of claim 11, wherein the first gate electrode and the second gate electrode are arranged in a line along the field insulating layer.

21. A method of manufacturing a semiconductor device, the method comprising:
forming a field insulating layer and a dummy gate on the field insulating layer;
performing a photoresist process comprising forming an etching area by etching the dummy gate;
forming a gate pattern bridge in the etching area; and
forming a first gate electrode and a second gate electrode in an area corresponding to the dummy gate such that the gate pattern bridge contacts a boundary between the first gate electrode and the second gate electrode.
